(19) United States
(12) Patent Application Publication
(10) Pub. No.: US 2023/0119460 A1
(43) Pub. Date: Apr. 20, 2023

(54) CHALCOGENIDE MATERIAL AND SEMICONDUCTOR MEMORY DEVICE INCLUDING CHALCOGENIDE MATERIAL

(71) Applicant: SK hynix Inc., Icheon (KR)

(72) Inventors: Jun Young LIM, Icheon (KR); Hyung Keun KIM, Icheon (KR)

(21) Appl. No.: 17/735,936

(22) Filed: May 3, 2022

(30) Foreign Application Priority Data
Oct. 18, 2021 (KR) 10-2021-0138714

(51) Int. Cl. H01L 45/00; H01L 27/24; G11C 13/00

(52) U.S. Cl. CPC H01L 45/143; H01L 27/2481; H01L 45/06; H01L 45/1233; G11C 13/0004; G11C 13/0023; G11C 2213/71

(57) ABSTRACT

The present disclosure relates to a chalcogenide material including germanium (Ge) with a first atomic percent, selenium (Se) with a second atomic percent that is at least twice the first atomic percent of the germanium, and indium (In) with a third atomic percent less the first atomic percent of the germanium.

### CROSS-REFERENCE TO RELATED APPLICATION

The present application claims priority under 35 U.S.C. § 119(a) to Korean patent application number 10-2021-0138714, filed on Oct. 18, 2021, which is incorporated herein by reference in its entirety.

### BACKGROUND

### Field of Invention

The present disclosure relates to a material of an electronic device and an electronic device, and more particularly, to a chalcogenide material and a semiconductor memory device including the chalcogenide material.

### Description of Related Art

An electronic device may include a semiconductor memory device for storing data. The semiconductor memory device may include memory cells each of which stores two or more types of logic states. The above-described semiconductor memory device may include a separate device for selecting a memory cell so as to program data in the memory cell, or read data stored in the memory cell.

In line with miniaturization and high performance of an electronic device, various technologies for increasing a degree of integration of memory cells and an operating speed at low power may be developed.

As the semiconductor memory device with the improved degree of integration and operating speed at low power, the next generation memory devices such as a random memory device (RAM), a phase change RAM (PRAM), a magnetic RAM (MRAM), and a resistive RAM (RRAM) have been proposed. Recently, the development of the next generation memory devices using a chalcogenide material which is beneficial to improve the degree of integration is underway.

### SUMMARY

According to an embodiment, a chalcogenide material may include germanium (Ge) with a first atomic percent, selenium (Se) with a second atomic percent that is at least twice the first atomic percent of the germanium, and indium (In) with a third atomic percent less than the first atomic percent of the germanium.

According to an embodiment, a semiconductor memory device may include a first conductive pattern, a second conductive pattern crossing the first conductive pattern, and a chalcogenide material layer disposed between the first conductive pattern and the second conductive pattern, the chalcogenide material layer including germanium (Ge) with a first atomic percent, selenium (Se) with a second atomic percent that is at least twice the first atomic percent of the germanium, and indium (In) with a third atomic percent less than the first atomic percent of the germanium.

### BRIEF DESCRIPTION OF THE DRAWINGS

FIG. 1 is a diagram illustrating a semiconductor memory device according to an embodiment of the present disclosure;

FIGS. 2A, 2B, and 2C are diagrams illustrating an example of a memory cell array of a semiconductor memory device according to embodiments of the present disclosure;

FIG. 3A is a graph illustrating a composition of a chalcogenide material; FIG. 3B is a graph illustrating leakage current characteristics according to a composition of a chalcogenide material;

FIG. 4 is a phase diagram of a binary compound semiconductor including germanium (Ge) and selenium (Se);

FIGS. 5A and 5B are graphs illustrating a threshold voltage Vth of a chalcogenide material according to the content of indium;

FIGS. 6A and 6B are graphs illustrating a threshold voltage Vth according to a thickness of a chalcogenide material layer;

FIG. 7 is a graph illustrating leakage current characteristics according to a thickness of a chalcogenide material layer;

FIGS. 8A and 8B are graphs illustrating a window margin of a chalcogenide material;

### DETAILED DESCRIPTION

The specific structural or functional descriptions disclosed herein are merely illustrative for the purpose of describing embodiments according to the concepts of the present disclosure. Embodiments according to the concepts of the present disclosure can be implemented in various forms and should not be construed as limited to the specific embodiments set forth herein.

Hereinafter, the terms ‘first’ and ‘second’ are used to distinguish one component from another component. As such, the components should not be limited by these terms.

Various embodiments are directed to a chalcogenide material capable of improving electrical characteristics of a binary compound semiconductor, and a semiconductor memory device including the chalcogenide material.

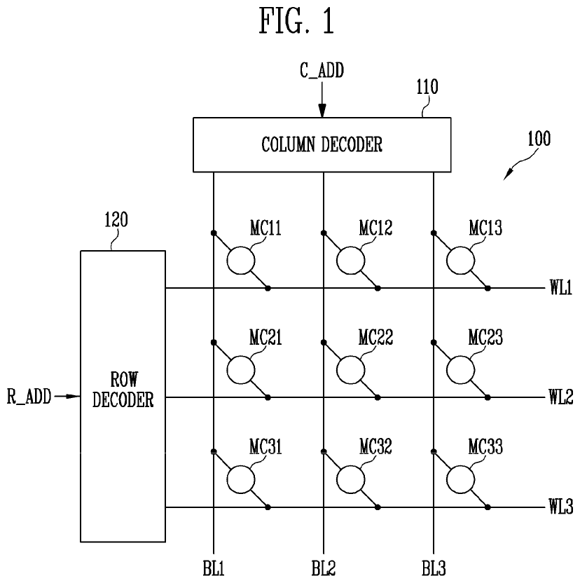

FIG. 1 is a diagram illustrating a semiconductor memory device according to an embodiment of the present disclosure.

Referring to FIG. 1, the semiconductor memory device may include a memory cell array 100, a column decoder 110, and a row decoder 120.

The memory cell array 100 may be coupled to a plurality of first signal lines and a plurality of second signal lines. The memory cell array 100 may include a plurality of memory cells MC11 to MC33 which are arranged at intersections between the plurality of first signal lines and the plurality of second signal lines. An embodiment of the present disclosure is described below using an example in which the plurality of first signal lines are word lines WL1 to WL3 and the plurality of second signal lines are bit lines BL1 to BL3. However, embodiments of the present disclosure are not limited thereto.

Each of the memory cells MC11 to MC33 may include a chalcogenide material with which a memory and a select device are embodied at the same time. According to an embodiment of the present disclosure, the memory cells MC11 to MC33 are formed using a material with which a memory and a select device are manufactured at the same time, so that the structure of the semiconductor memory device may be simplified, manufacturing costs may be reduced, and a degree of integration may be improved.

A distribution of ions within a chalcogenide material may vary depending on the polarity of a program pulse. Due to such characteristics, each of the memory cells MC11 to MC33 may have a threshold voltage which varies according to the polarity of the program pulse. For example, when the first memory cell MC11 is programmed by a first program pulse having a first polarity, the first memory cell MC11 may have a first threshold voltage. When the first memory cell MC11 is programmed by a second program pulse having a second polarity opposite to the first polarity, the first memory cell MC11 may have a second threshold voltage having a different level from the first threshold voltage. An absolute value of the first program pulse may be the same as, or different from an absolute value of the second program pulse. A width of the first program pulse may be the same as, or different from a width of the second program pulse.

A program state having the first threshold voltage and a program state having the second threshold voltage may be referred to as a set state and a reset state, respectively. For example, the first threshold voltage may have a lower level than the second threshold voltage. The set state may refer to a program state having a first threshold voltage at a relatively low level. The reset state may refer to a program state having a second threshold voltage at a relatively high level. The chalcogenide material may maintain an amorphous state even when the program pulse which is set to program a memory cell to the reset state and a program pulse which is set to program a memory cell to the set state are applied.

A read operation of reading data stored in the memory cells MC11 to MC33 may be performed to identify data stored in the memory cells MC11 to MC33 by determining the polarity of the program pulse using a polarity of a read pulse. According to an embodiment, during a read operation, a read pulse having a first polarity or a read pulse having a second polarity may be used. When the program pulse and the read pulse have the same polarity, a first resistance value may be detected. On the other hand, when the polarity of the program pulse is opposite to the polarity of the read pulse, a second resistance value different from the first resistance value may be detected. Therefore, the polarity of the program pulse may be determined based on the resistance value which is detected when the read pulse is applied. The data stored in the memory cells MC11 to MC33 may be identified using the determined polarity of the program pulse.

The polarity may be determined by a potential difference between a selected bit line and a selected word line. For example, the first polarity may be a positive polarity and the second polarity may be a negative polarity. For example, the positive polarity may be defined as a polarity when a voltage applied to the selected bit line is greater than a voltage applied to the selected word line. The negative polarity may be defined as a polarity when the voltage applied to the selected bit line is less than the voltage applied to the selected word line.

The memory cell array 100 may be coupled to the column decoder 110 through the bit lines BL1 to BL3. The column decoder 110 may select at least one of the bit lines BL1 to BL3 in response to a column address C_ADD. The column decoder 110 may transfer operating voltages for a program operation and a read operation to the bit lines BL1 to BL3.

The memory cell array 100 may be coupled to the row decoder 120 through the word lines WL1 to WL3. The row decoder 120 may select at least one of the word lines WL1 to WL3 in response to a row address R_ADD. The row decoder 120 may transfer operating voltages for a program operation and a read operation to the word lines WL1 to WL3.

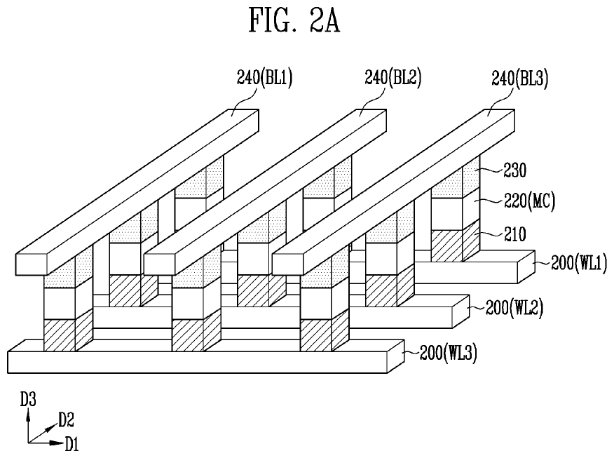

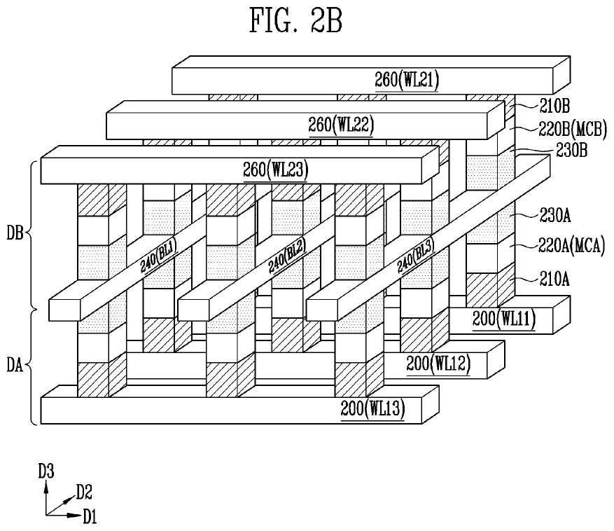

FIGS. 2A, 2B, and 2C are diagrams illustrating an example of the memory cell array 100 of the semiconductor memory device according to embodiments of the present disclosure. A first direction D1, a second direction D2, and a third direction D3 which are defined below may correspond to directions in which axes crossing each other extend. According to an embodiment, the first direction D1, the second direction D2, and the third direction D3 may correspond to the x-axis, the y-axis, and the z-axis on the XYZ coordinate system, respectively.

Referring to FIG. 2A, the memory cell array may be configured as a single deck which includes a plurality of first conductive patterns 200, a plurality of second conductive patterns 240, and a plurality of memory cells MC.

The plurality of first conductive patterns 200 may extend in the first direction D1 and serve as the plurality of word lines WL1 to WL3. The plurality of second conductive patterns 240 may be arranged on the plurality of first conductive patterns 200 and extend in the second direction D2. The plurality of second conductive patterns 240 may serve as the plurality of bit lines BL1 to BL3.

Each of the memory cells MC may be arranged at an intersection between the first conductive pattern 200 and the second conductive pattern 240 and may be disposed between the first conductive pattern 200 and the second conductive pattern 240. The memory cell MC may include a chalcogenide material 220.

The memory cell array may further include a lower electrode 210 which is disposed between the chalcogenide material (or chalcogenide material layer) 220 and the first conductive pattern 200, and an upper electrode 230 which is disposed between the chalcogenide material 220 and the second conductive pattern 240. Two or more memory cells MC which are arranged next to each other in the first direction D1 may be coupled in parallel with each other on each of the first conductive patterns 200. A voltage which is applied to each of the first conductive patterns 200 may be applied to the chalcogenide material 220 through the lower electrode 210. Two or more memory cells MC which are arranged next to each other in the second direction D2 may be coupled in parallel with each other on each of the second conductive patterns 240. A voltage which is applied to each of the second conductive patterns 240 may be applied to the chalcogenide material 220 through the upper electrode 230.

Referring to FIG. 2B, the memory cell array may be configured as a multi-deck in which two or more decks are stacked on top of each other. According to an embodiment, the memory cell array may include a first deck DA and a second deck DB over the first deck DA.

The first deck DA may include the plurality of first conductive patterns 200, the plurality of second conductive patterns 240, and a plurality of first memory cells MCA. The first deck DA may further include a first lower electrode 210A which is disposed between the first memory cell MCA and the first conductive pattern 200, and a first upper electrode 230A which is disposed between the first memory cell MCA and the second conductive pattern 240.

The plurality of first conductive patterns 200, the plurality of second conductive patterns 240, the first lower electrode 210A, and the first upper electrode 230A may have the same structures as the plurality of first conductive patterns 200, the plurality of second conductive patterns 240, the lower electrode 210, and the upper electrode 230 as shown in FIG. 2A, respectively.

The second deck DB may include the plurality of second conductive patterns 240, a plurality of third conductive patterns 260, and a plurality of second memory cells MCB. The plurality of second conductive patterns 240 may be shared between the first deck DA and the second deck DB.

The plurality of third conductive patterns 260 may be arranged above the plurality of second conductive patterns 240 and extend to cross the plurality of second conductive patterns 240. In an embodiment, the plurality of third conductive patterns 260 may extend in the first direction D1 to cross the plurality of second conductive patterns 240.

Each of the second memory cells MCB may be arranged at an intersection between the second conductive pattern 240 and the third conductive pattern 260 and may be disposed between the second conductive pattern 240 and the third conductive pattern 260.

The second deck DB may further include a second lower electrode 230B which is disposed between the second memory cell MCB and the second conductive pattern 240, and a second upper electrode 210B which is disposed between the second memory cell MCB and the third conductive pattern 260.

Two or more second memory cells MCB which are arranged next to each other in the second direction D2 may be coupled in parallel with each other on each of the second conductive patterns 240. A voltage which is applied to each of the second conductive patterns 240 may be applied to the second memory cell MCB through the second lower electrode 230B. Two or more second memory cells MCB which are arranged next to each other in the first direction D1 may be coupled in parallel with each other on each of the third conductive patterns 260. A voltage which is applied to each of the third conductive patterns 260 may be applied to the second memory cell MCB through the second upper electrode 210B.

The plurality of first conductive patterns 200 and the plurality of third conductive patterns 260 may serve as a plurality of word lines (WL11 to WL13 and WL21 to WL23). The plurality of second conductive patterns 240 may serve as the plurality of bit lines BL1 to BL3.

The first memory cell MCA may include a first chalcogenide material (or first chalcogenide material layer) 220A and the second memory cell MCB may include a second chalcogenide material (or second chalcogenide material layer) 220B.

Referring to FIG. 2C, the memory cell array may be realized as a three-dimensional memory cell array. The three-dimensional memory cell array may include a plurality of first conductive patterns 200C, a plurality of second conductive patterns 240C crossing the plurality of first conductive patterns 200C, and a plurality of chalcogenide materials (or a plurality of chalcogenide material layers) 220C formed at interconnections between the plurality of first conductive patterns 200C and the plurality of second conductive patterns 240C.

Each of the first conductive patterns 200C may be in the form of a flat panel which extends in the first direction D1 and the second direction D2. The plurality of first conductive patterns 200C may be stacked on top of each other so as to be separated from each other in the third direction D3. The plurality of first conductive patterns 200C may serve as the plurality of word lines WL1 to WL3.

The plurality of second conductive patterns 240C may extend in the third direction D3 to pass through the plurality of first conductive patterns 200C. Though not shown in FIG. 2C, a plurality of bit lines which are coupled to the plurality of second conductive patterns 240C may be arranged over the plurality of second conductive patterns 240C. Each of the chalcogenide material 220C may surround a sidewall of each of the second conductive patterns 240C corresponding thereto. Some areas of the chalcogenide materials 220C arranged at the intersections between the plurality of first conductive patterns 200C and the plurality of second conductive patterns 240C may serve as memory cells. Though not shown in FIG. 2C, a dielectric layer may be arranged between each of the first conductive patterns 200C and each of the chalcogenide materials 220C.

A memory and a select device may be embodied at the same time using each of the chalcogenide materials 220, 220A, 220B, and 220C as shown in FIGS. 2A, 2B, and 2C. Each of the chalcogenide materials 220, 220A, 220B, and 220C may mainly include a binary compound semiconductor of germanium (Ge) and selenium (Se), and may further include indium (In). A composition ratio between Ge, Se, and In which form each of the chalcogenide materials 220, 220A, 220B, and 220C may be controlled so as to ensure desirable electrical characteristics. According to an embodiment, each of the chalcogenide materials 220, 220A, 220B, and 220C may have a composition which includes germanium (Ge), selenium (Se) having an atomic percent twice or more than twice as great as an atomic percent of germanium, and indium (In) having an atomic percent smaller than each of those of germanium and selenium. In an embodiment, the sum of the atomic percent of germanium, the atomic percent of selenium, and the atomic percent of indium may be substantially 100% (e.g., at least 99%). In an embodiment, the sum of the atomic percent of germanium, the atomic percent of selenium, and the atomic percent of indium may be equal to or greater than 99.5%, 99.7%, or 99.9%. In other words, according to an embodiment of the present disclosure, the composition of each of the chalcogenide materials 220, 220A, 220B, and 220C may exclude arsenic (As) which is an element in a high risk group. For example, if a chalcogenide material includes arsenic, disposal costs and environmental pollution associated with a memory device including the chalcogenide material may be increased and safety concerns may arise in processing the chalcogenide material. When arsenic is excluded, waste disposal costs and environmental pollution may be reduced and the safety of a workplace for processing the chalcogenide material may be improved. In an embodiment, a chalcogenide material according to an embodiment of the present disclosure may contain substantially no arsenic.

According to an embodiment of the present disclosure, a composition ratio of germanium, selenium, and indium may be controlled so as to be in a range which stably enables an operation of a memory cell. According to an embodiment, germanium may be included within a range from 25 at % to 32 at % in the chalcogenide material 220, 220A, 220B, or 220C, selenium may be included within a range from 50 at % to 66 at % in the chalcogenide material 220, 220A, 220B, or 220C, and indium may be included within a range from 1 at % to 12 at % in the chalcogenide material 220, 220A, 220B, or 220C. The chalcogenide material 220, 220A, 220B, or 220C may maintain an amorphous state at a temperature of 600° C. or less. Hereinafter, electrical characteristics which may be ensured by controlling the above-described composition ratio in various experimental groups will be described.

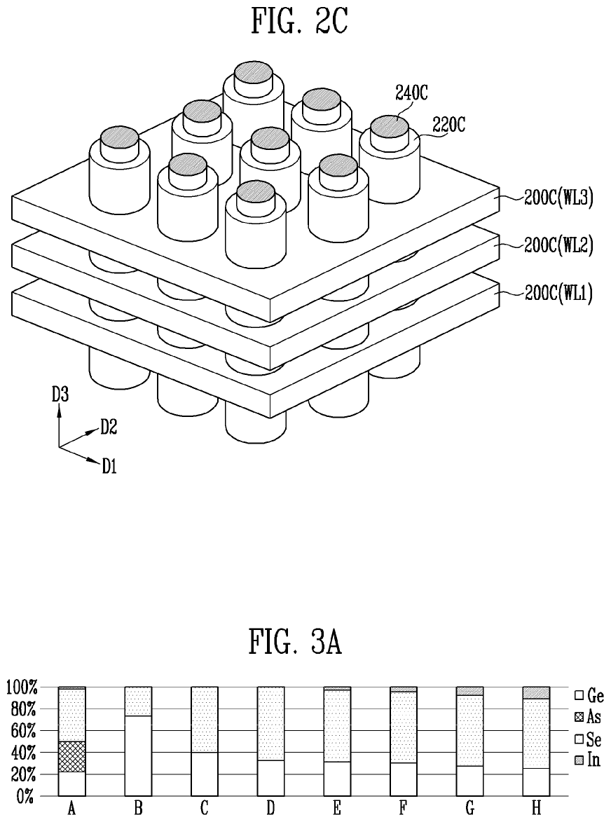

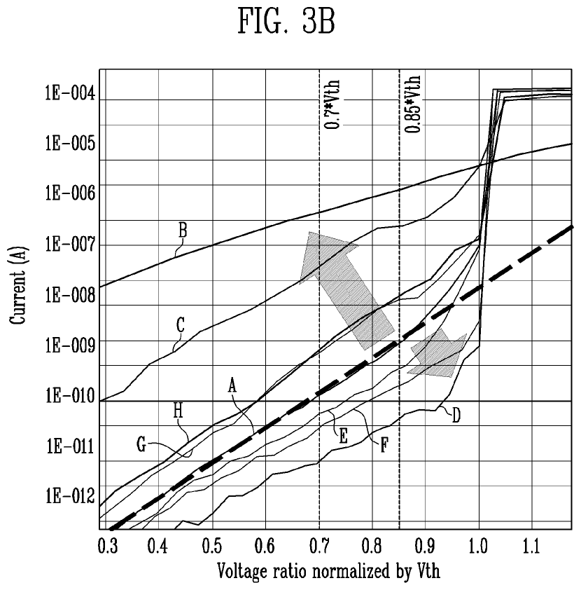

FIG. 3A is a graph illustrating a composition of a chalcogenide material. FIG. 3B is a graph illustrating leakage current characteristics according to the composition of the chalcogenide material. In FIG. 3B, the x-axis represents a voltage ratio normalized by a threshold voltage Vth and the y-axis represents a current.

Referring to FIG. 3A and [Table 1] below, a split A may correspond to a control group, and splits B, C, D, E, F, G, and H may correspond to experimental groups. A percentage as shown in FIG. 3A and [Table 1] may indicate an atomic percent (at %).

TABLE 1

| | Split | | | | | | | |
|---|---|---|---|---|---|---|---|---|
| | A | B | C | D | E | F | G | H |
| Material | Ge/As/Se/In | Ge/Se | | | Ge/Se/In | | | |
| Ge | See | 73.4% | 40.0% | 33.2% | 31.8% | 30.4% | 27.6% | 25.6% |
| As | FIG. | — | — | — | — | — | — | — |
| Se | 3A | 26.6% | 60.0% | 66.8% | 65.5% | 65.1% | 64.4% | 63.4% |
| In | | — | — | — | 2.7% | 4.6% | 8.0% | 11.0% |

The split A may correspond to a chalcogenide material with electrical characteristics which may stably enable an operation of a memory cell. The split A may provide a reference value for identifying the electrical characteristics of the experimental groups. The split A may include germanium, selenium, indium, and arsenic. Each of the splits B, C, and D may be a chalcogenide material which excludes arsenic.

Referring to [Table 1] and FIGS. 3A and 3B, even if arsenic is excluded, when the atomic percent of selenium is increased to be at least twice that of germanium, good leakage current characteristics as in the splits D, E, F, G, and H, may be obtained. For example, although it is known that excluding arsenic may deteriorate leakage current characteristics, the leakage current characteristics may be improved, rather than being deteriorated, when the atomic percent of selenium is increased to be at least twice that of germanium. Therefore, leakage current characteristics of a binary compound semiconductor which includes arsenic and selenium may be ensured by increasing the atomic percent of selenium twice or more than twice as much as that of germanium.

In an embodiment, leakage current characteristics may be ensured by controlling the content of germanium in the chalcogenide material to be in the range from about 25 at % (e.g., from 24.5 to 25.4 at %) to about 32 at % (e.g., from 31.5 to 32.4 at %) and controlling the content of selenium to be in the range from about 50 at % to about 66 at %. For example, as shown in splits E, F, G, and H of Table 1 and FIGS. 3A and 3B, leakage current characteristics may be sufficiently ensured when the atomic percent of germanium is in the range from 25 at % to 32 at % and the atomic percent of selenium is in the range from 63 at % to 66 at %.

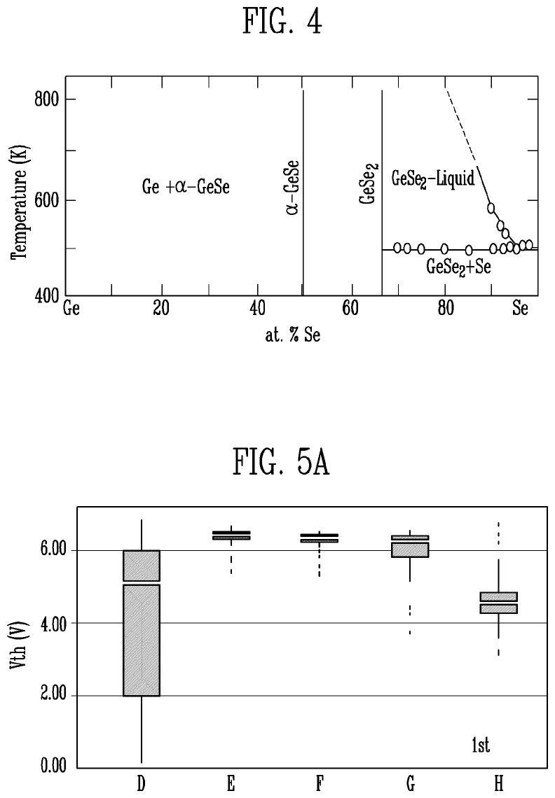

FIG. 4 is a phase diagram of a binary compound semiconductor including germanium (Ge) and selenium (Se).

Referring to FIG. 4, in a composition where germanium and selenium are dominant, α-GeSe and GeSe₂ may have phase stability. Therefore, the phase stability of the binary compound semiconductor based on germanium and selenium may be ensured by controlling the atomic percent of selenium to be twice or more than twice as much as that of the atomic percent of germanium.

Referring to FIGS. 3A and 3B, [Table 1], and FIG. 4, by controlling the atomic percent of selenium to be twice or more than twice as much as the atomic percent of germanium by about 1 at % to about 12 at %, both phase stability and leakage current characteristics may be ensured. For example, when germanium is included at a ratio of about [N] at % in the chalcogenide material, about [2N] at % selenium may be included in the chalcogenide material, or selenium may be included in a range from about [2N+1] to about [2N+12] at %, N being an integer.

As a result of performing an annealing process up to a temperature of 600° C. with the contents of germanium and selenium limited to the above ratios, the chalcogenide material having the above-described composition and including germanium and selenium may maintain an amorphous state at a temperature of up to 600° C. As described above, according to an embodiment of the present disclosure, because a chalcogenide material maintains an amorphous state at a temperature of 600° C. or less, crystallization of the chalcogenide material caused by heat generated during the manufacturing processes of a semiconductor memory device may be substantially prevented. Therefore, according to an embodiment of the present disclosure, stability and reliability of the manufacturing processes may be improved.

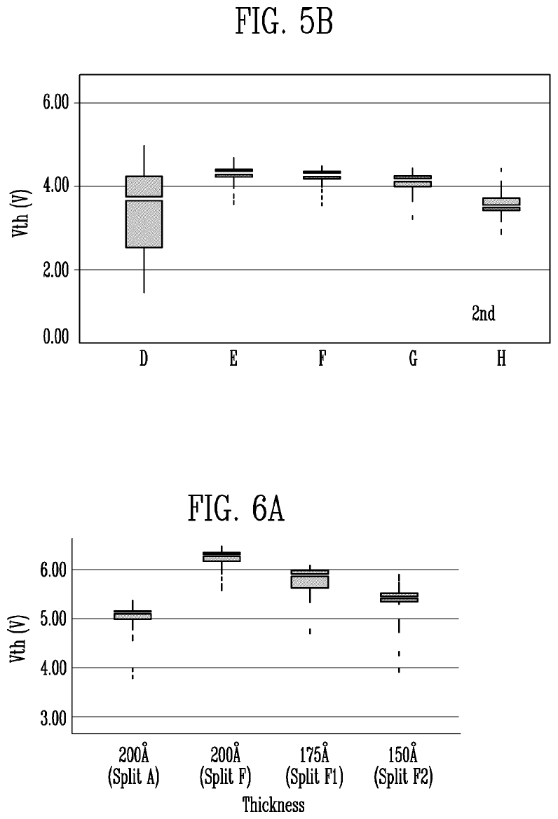

The split D which includes only the binary compound semiconductor of germanium and selenium may have a threshold voltage higher than a target range. Indium may have a lower bandgap than GeSe₂. Thus, by adding indium to a binary compound semiconductor including germanium and selenium, a threshold voltage of the Ge and Se-based binary compound semiconductor may be reduced. Indium may be doped into the chalcogenide material by a sputtering process. A composition ratio of indium may be controlled by adjusting a ratio of power which is applied to sputtering equipment. Hereinafter, electrical characteristics of a chalcogenide material depending on the indium content will be described with reference to FIGS. 5A and 5B.

FIGS. 5A and 5B are graphs illustrating the threshold voltage Vth of a chalcogenide material depending on the content of indium. FIG. 5A is a graph illustrating the threshold voltage Vth of the splits D, E, F, G, and H when an initial pulse is applied after the manufacturing processes are completed. FIG. 5B is a graph illustrating the threshold voltage Vth of the splits D, E, F, G, and H when the same pulse as the initial pulse is repeatedly applied.

Referring to FIGS. 5A and 5B, the threshold voltage distribution width of each of the splits E, F, G, and H may be reduced compared to a threshold voltage distribution width of the split D. By including indium in a range from about 1 at % (e.g., from 0.5 to 1.4 at %) to about 12 at % (e.g., from 11.5 to 12.4 at %) in the chalcogenide material including germanium, selenium and indium, such as the splits E, F, G, and H, the threshold voltage may be controlled to be in a target range (e.g., from 3 V to 7 V). For example, the chalcogenide material including indium in a range from 2 at % to 11 at %.

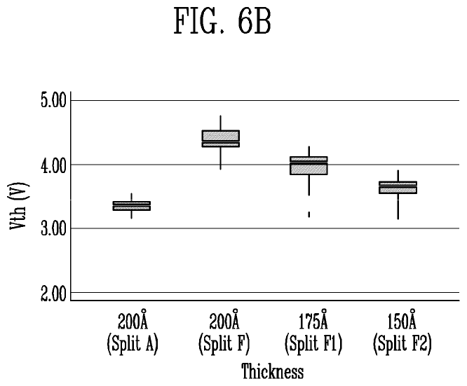

FIGS. 6A and 6B are graphs illustrating the threshold voltage Vth according to a thickness of a chalcogenide material layer. FIGS. 6A and 6B show the threshold voltage Vth obtained by changing the thickness of the chalcogenide material layer which has the same composition as the split F among the splits E, F, G, and H which have effective electrical characteristics. FIG. 6A is a graph illustrating the threshold voltage Vth of the splits A, F, F1 and F2 when the initial pulse is applied after the completion of the manufacturing processes. FIG. 6B is a graph illustrating the threshold voltage Vth of the splits A, F, F1, and F2 when the same pulse as the initial pulse is repeatedly applied. The splits F1 and F2 in the experimental group may have substantially the same composition as the split F and have a different thickness from the split F. For example, in the embodiment of FIGS. 6A and 6B, the splits F, F1 and F2 may correspond to chalcogenide material layers having thicknesses of 200 Å, 175 Å, and 150 Å, respectively.

Referring to FIGS. 6A and 6B, by controlling a deposition thickness of the chalcogenide material layer having the same composition ratio so as to be in a range from 150 Å to 200 Å, the chalcogenide material layer having a threshold voltage in a target range (e.g., from 3 V to 7 V) may be provided.

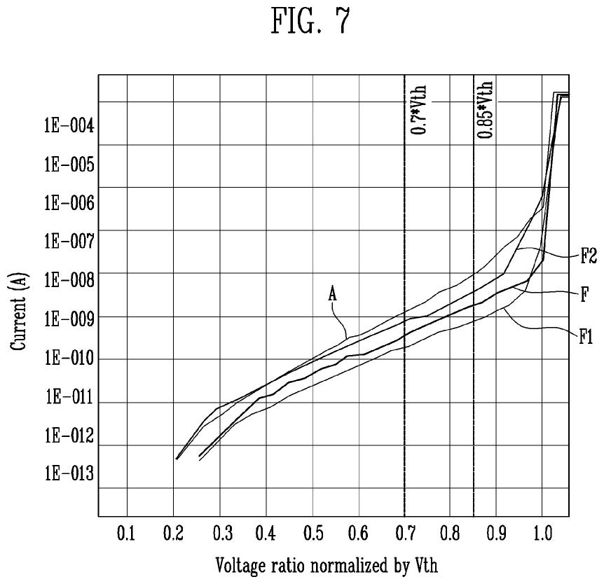

FIG. 7 is a graph illustrating leakage current characteristics according to a thickness of a chalcogenide material layer. FIG. 7 illustrates leakage current characteristics with respect to the splits A, F, F1, and F2 as shown in FIGS. 6A and 6B.

Referring to FIG. 7, when the deposition thickness of the chalcogenide material layer having the same composition ratio is controlled to be in the range from 150 Å to 200 Å, better leakage current characteristics than the split A may be provided.

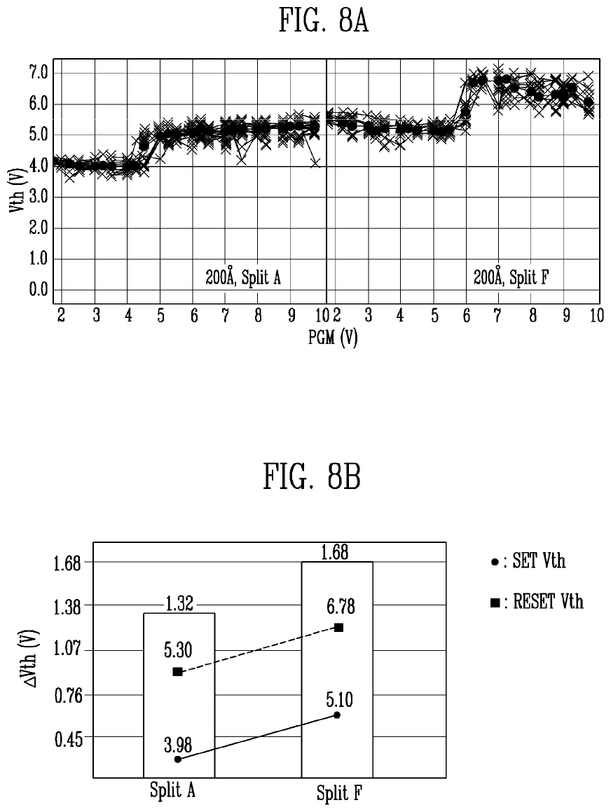

FIGS. 8A and 8B are graphs illustrating a window margin of a chalcogenide material. FIGS. 8A and 8B are graphs illustrating window margins of the splits F and A among the splits E, F, G, and H which have effective electrical characteristics.

Referring to FIGS. 8A and 8B, on the basis of a program voltage of 4.5 V, the threshold voltage Vth of the split A in a set state may be 3.98 V and the threshold voltage Vth of the split A in a reset state may be 5.3 V. Therefore, the split A may have a window margin of 1.32 V. On the basis of the program voltage of 4.5 V, the threshold voltage Vth of the split F in the set state may be 5.1 V and the threshold voltage Vth of the split F in the reset state may be 6.78 V. Therefore, the split F may have a window margin of 1.68 V which is higher than that (i.e., 1.32V) of the split A.

As described above, germanium, selenium which has an atomic percent twice or more than twice as much an atomic percent of germanium, and a chalcogenide material which has a smaller atomic percent than each of the atomic percent of germanium and the atomic percent of selenium according to an embodiment of the present disclosure may be used as materials for forming a memory and a select device.

A chalcogenide material according to an embodiment of the present disclosure may have desirable threshold voltage switching characteristics as described above (e.g., as shown in FIGS. 3B, 5A, 5B, 6A, 6B, and 7). Therefore, the chalcogenide material according to an embodiment of the present disclosure may be used to form a select device of various electronic devices. According to an embodiment of the present disclosure, a chalcogenide material may be applied as a material of a select device which is connected to a variable resistance memory cell which includes a phase-change material layer.

According to the present disclosure, electrical characteristics of a chalcogenide material may be improved by forming the chalcogenide material in which a binary compound including germanium (Ge) and selenium (Se) is combined with indium (In).

What is claimed is:

1. A chalcogenide material comprising:
germanium (Ge) with a first atomic percent, selenium (Se) with a second atomic percent that is at least twice the first atomic percent of the germanium, and indium (In) with a third atomic percent less than the first atomic percent of the germanium.

2. The chalcogenide material of claim 1, wherein a total sum of the first atomic percent of the germanium, the second atomic percent of the selenium, and the third atomic percent of the indium is substantially 100%.

3. The chalcogenide material of claim 1, wherein the first atomic percent of the germanium is in a range from about 25 at % to about 32 at %.

4. The chalcogenide material of claim 1, wherein the second atomic percent of the selenium is in a range from about 50 at % to about 66 at %.

5. The chalcogenide material of claim 1, wherein the third atomic percent of the indium is in a range from about 1 at % to about 12 at %.

6. The chalcogenide material of claim 1, wherein the first atomic percent of the germanium is about [N] at %, N being an integer, and
wherein the second atomic percent of the selenium is in a range from about [2N+1] at % to about [2N+12] at %.

7. The chalcogenide material of claim 1, wherein the material maintains an amorphous state at a temperature of 600° C. or less.

8. The chalcogenide material of claim 1, wherein the first atomic percent of the germanium is in a range from 25 at % to 32 at %,
wherein the second atomic percent of the selenium is in the range from 63 at % to 66 at %, and
wherein the third atomic percent of the indium is in the range from 2 at % to 11 at %.

9. A semiconductor memory device, comprising:
a first conductive pattern;
a second conductive pattern crossing the first conductive pattern; and
a chalcogenide material layer disposed between the first conductive pattern and the second conductive pattern, the chalcogenide material layer including germanium (Ge) with a first atomic percent, selenium (Se) with a second atomic percent, and indium (In) with a third atomic percent,
wherein the second atomic percent is at least twice that of the first atomic percent, and the third atomic percent is less than the first atomic percent.

10. The semiconductor memory device of claim 9, wherein a total sum of the first atomic percent of the germanium, the second atomic percent of the selenium, and the third atomic percent of the indium is substantially 100%.

11. The semiconductor memory device of claim 9, wherein the first atomic percent of the germanium is in a range from about 25 at % to about 32 at %.

12. The semiconductor memory device of claim 9, wherein the second atomic percent of the selenium is in a range from about 50 at % to about 66 at %.

13. The semiconductor memory device of claim 9, wherein the third atomic percent of the indium is in a range from about 1 at % to about 12 at %.

14. The semiconductor memory device of claim 9, wherein the first atomic percent of the germanium is about [N] at %, N being an integer, and
wherein the second atomic percent of the selenium is in a range from about [2N+1] at % to about [2N+12] at %.

15. The semiconductor memory device of claim 9, wherein the chalcogenide material layer maintains an amorphous state at a temperature of 600° C.

16. The semiconductor memory device of claim 9, wherein the first atomic percent of the germanium is in a range from 25 at % to 32 at %,
wherein the second atomic percent of the selenium is in the range from 63 at % to 66 at %, and
wherein the third atomic percent of the indium is in the range from 2 at % to 11 at %.

17. The semiconductor memory device of claim 9, wherein the chalcogenide material layer has a thickness in a range from 150 Å to 200 Å.

18. The semiconductor memory device of claim 9, wherein the chalcogenide material layer surrounds a sidewall of the second conductive pattern.
